(19) United States
(12) Patent Application Publication
(10) Pub. No.: US 2026/0123502 A1
(43) Pub. Date: Apr. 30, 2026

(54) METHOD OF JOINING ELECTRICAL AND MECHANICAL COMPONENTS USING LAMINATED MODULAR PREFORMS

(71) Applicant: Alpha Assembly Solutions Inc., Waterbury, CT (US)

(72) Inventors: Maurizio FENECH, Waterbury, CT (US); Oscar KHASELEV, Waterbury, CT (US); Andres SOCARRAS, Waterbury, CT (US); Matthew SIEBENHUHNER, Waterbury, CT (US); Bawa SINGH, Waterbury, CT (US)

(21) Appl. No.: 18/729,056

(22) PCT Filed: Jan. 20, 2023
(86) PCT No.: PCT/EP2023/025024

§ 371 Date: Mar. 12, 2025

Related U.S. Application Data
(60) Provisional application No. 63/301,204, filed on Jan. 20, 2022.

(51) Int. Cl. H01L 21/603; H01L 21/67; H01L 23/00

(52) U.S. Cl. CPC H10W 72/07232; H10P 72/0444; H10W 72/07331

(57) ABSTRACT

A method of applying a sinterable film to a substrate during a surface mount technology (SMT) process comprises: providing a substrate; providing a preform comprising a support film, the support film having a first surface and a second surface opposite the first surface, the support film being laminated with a sinterable film of metal particles (e.g., Ag, Ag alloy, Au, Au alloy, Cu, Cu alloy, Rd, Rd alloy, Ni, Ni alloy, Al, Al alloy, Ag-coated Cu, Cu-coated Ag) on the first surface but not on the second surface; providing a pick-and-place machine comprising a placement head; picking up the preform via the second surface using the placement head of the pick-and-place machine; placing the preform in contact with the substrate using the pick-and-place machine, wherein the contact is via the sinterable film; attaching the sinterable film to the substrate; and separating the support film from the sinterable film. The placement head may comprise a vacuum nozzle, wherein picking up the preform via the support film comprises applying a vacuum to the second surface using the vacuum nozzle. Separating the support film from the sinterable film may be carried out by moving the placement head of the pick-and-place machine away from the support film while maintaining the vacuum. The support film may be discarded from the pick-and-place machine by removing the vacuum. The support film may be used to manufacture a further preform.

The present invention relates generally to a method of applying a sinterable film to a substrate; a method of forming a stack of sinterable films on a substrate; a method of attaching a die to a substrate; a method of attaching a clip, bond pad or top-side bridging structure to a die and a substrate; and a method of manufacturing an electronic device.

Sintering powders contain nano- or micron-sized metal particles. They may be used to form a sintered joint between electronic components by placing the sintering powder between the electronic components and then sintering the sintering powder. The use of a sintering powder may enable the formation of a joint at a lower temperature than the melting temperature of the said powder and the melting temperature of conventional high temperature solders. Sintered silver electronic component-attach materials combine unique physical properties of nanosilver powder and advanced chemical formulations into the innovative products, which allow joining various electronic devices to produce a high thermal and electrical conductivity interfaces with extreme functional reliability.

Applying sinter material in the form of a paste through the printing method presents difficulties especially when application is necessary in awkward places such as on complex circuit boards or on elevated devices. Persistent problems, such as inhomogeneity of the print profile, difficult access of stencils in recessed positions and stencil/substrate leakage, are common. In a conventional printing method, a metal stencil having a thickness in the range of 50 μm to 300 μm and having an opening in the form of a screen or a blank is used to produce a cavity on top of the target surface. The process of printing involves running a volume of paste over the metal stencil using a dedicated wiper. The paste fills the opening and assumes its X-Y pattern and the height of the stencil thickness. After application of the paste, the stencil is removed and the paste is allowed to dry in a dedicated oven at a temperature range of 140° C. to 170° C. before the target component (in the form of a power chip, a temperature sensor, a conducting/isolating spacer and so forth) is placed on top and is sintered through the application of pressure (10-25 MPa), heat (210-270° C.) and time (60-480 s). The printing technique is well suited for applying paste on flat surfaces and when cavities are in the 15 mm²-400 mm² range. However, significant challenges exist when paste needs to be applied on smaller or larger areas (due to printing artifacts) or when paste needs to be applied in three dimensions, where the stencil would physically interfere with the already present components. Printing on top of the surface of target components is also very difficult, necessitating the use of three-dimensional stencils that suffer from considerable amount of paste wastage, under-stencil leaking and printing artefacts that include non-homogeneous printed-paste thickness.

Application of sintering powders in the form of a film or preform instead of a paste is a possibility that allows better bond line control, access to otherwise inaccessible places such as cavities as well as enabling a modular approach in building a module. Silver films can be applied or laminated to the backside of a die, a wafer or any other compatible electronic component.

U.S. Pat. No. 10,710,336B2 describes the use of a sintering film comprised of nano sinter material reinforced either by particles or by an intermediate foil to produce a free standing preform that can be used for the attachment of electronic devices. After sintering, reinforcing particles or the intermediate foil remain in the sintered joint, making a pure nano-silver sintered joint not possible and thereby potentially adversely affecting the properties of the sintered joint. Both the reinforcing particles and silver foil increase the cost of the film through addition of materials and processing steps. The free standing film is typically damaged when handled by a conventional pick-and-place machine.

Sintering films are also described in US 2012/0114927A1. This document also describes methods of transferring a sintering film to a die or substrate. In one of the methods, (known in the art as “Die Transfer Film”, or DTF), sinterable material in the form of film is placed on top of a rubberized holder within an automated pick and place workspace ready for processing. The prepared film and rubberized holder assembly is referred to as the film station. During the processing, a target component (in the form of a power chip, a temperature sensor, a conducting/isolating spacer and so forth) is picked up by the pick and place bond head from its holding station and moved over to the prepared film. Afterwards, the target component is pressed onto the film using a pressure in the region of 2-5 MPa and a temperature of 130° C. to170° C. and a time of 100-500 ms. In these pressing conditions the sinterable film is laminated to the bottom-side of the target component. Following the lamination process, the target component is lifted from the film station and moved over to the target surface where it is pressed onto the target surface using a pressure in the region of 3-5 MPa and a temperature of 130° C. to 170° C. and a time of 200-800 ms. After the pressing process, the target component is attached to the target surface with a mild attachment strength that is adequate for transportation of the unfinished power module to the sintering step. Sintering is then achieved by the application of pressure (10-25 MPa), heat (210-270° C.) and time (60-480 s) to achieve a fully sintered joint. Die Transfer Film technology is well suited to laminate the bottom of target components with very uniform sinterable material, but it is limited to processes where the lamination is achieved on the bottom of discrete sinterable components. Applying the Die transfer Film concept for laminating the top of target components or for putting film-based sinterable materials on specific areas of target surfaces is inherently not possible.

The present invention aims to solve at least some of the problems associated with the prior art or to provide a commercially acceptable alternative.

In a first aspect, the present invention provides a method of applying a sinterable film to a substrate during a surface mount technology (SMT) process, the method comprising:
providing a substrate;
providing a preform comprising a support film, the support film having a first surface and a second surface opposite the first surface, the support film being laminated with a sinterable film of metal particles on the first surface but not on the second surface;
providing a pick-and-place machine comprising a placement head;
picking up the preform via the second surface using the placement head of the pick-and-place machine,
placing the preform in contact with the substrate using the pick-and-place machine, wherein the contact is via the sinterable film;
attaching the sinterable film to the substrate; and
separating the support film from the sinterable film.

The present invention will now be further described. In the following passages different aspects of the invention are defined in more detail. Each aspect so defined may be combined with any other aspect or aspects unless clearly indicated to the contrary. In particular, any feature indicated as being preferred or advantageous may be combined with any other feature or features indicated as being preferred or advantageous.

Surprisingly, in contrast to printing methods, the method of the present invention enables the application of very uniform and homogeneous sinterable material on target surfaces, in sizes ranging from, for example, 1 mm² to 100 mm². The method of the present invention may also enable sinterable material to be applied in a fully dry condition, i.e. without the presence of solvent, meaning that a separate drying step is not required.

Advantageously, in contrast to the DTF method, the method of the present invention enables sinterable material to be applied in hard-to-reach places, such as in a recess of a substrate or on top of a die or clip that has already been attached to a substrate. The sinterable material may also be applied in a desired shape and size that does not necessary conform to the shape and size of the surface to which it is applied.

In conventional surface mount technology (SMT) methods, components are typically laminated with a sinterable film and then placed on a substrate. In the present invention, the lamination process is separated from the component handling process. Since not all components can be laminated the present invention therefore enables sinterable film to be placed specifically where it is required.

The present invention may enable the sequential application of multiple sinterable films on the same portion of a substrate. This enables one to control the thickness of the final sinterable film.

### The Method May Achieve Attachment of the Sinterable Film Without the Use of a tacking agent.

In contrast to the sinterable films of U.S. Pat. No. 10,710,336B2, the sinterable films of the present invention are preferably substantially free (more preferably entirely free) of support particles (e.g. non-metal particles such as graphite, carbon or glass), i.e. solid particles other than the metal particles. Such support particles are not necessary in the sinterable film of the present invention in view of the support film and in view of the fact that the film is not required to be free-standing. Furthermore, such support particles may adversely affect the properties of the final sintered joint and/or increase the cost of the sintrerable film. In contrast to the sinterable films of U.S. Pat. No. 10,710,336B2, the sinterable films of the present invention are preferably free of a silver foil layer. Such a silver foil layer is not necessary in view of the support film. Furthermore, in view of the manner in which the pick-and-place machine handles the sinterable film, it is never required to be free-standing. Such a silver layer may increase the cost of the sinterable film.

The term “surface mount technology (SMT) process” as used herein may encompass a process in which electrical components are mounted directly onto the surface of a printed circuit board (PCB).

The term “preform” as used herein may encompass a pre-made shape of sinterable particles specially designed for the application where it is to be used. The support film of the preform has first and second surfaces. The first and second surfaces are the major, i.e. largest surfaces of the film. The support film is laminated with a sinterable film of metal particles on the first surface. Typically, the sinterable film of metal particles covers the entirety of the first surface.

The metal particles of the sinterable film may be in the form of, for example, spheres, rods and/or plates.

Providing the preform may comprise laser cutting to ensure that the preform is of the desired size and shape. For example, a large support film may be provided having a film of sinterable particles on a first surface thereof but not on a second surface thereof. The large support film may then be cut into one or more preforms of the desired size and shape using continuous wave or short pulse ablative laser cutting. Laser cutting enables the preforms to be prepared with a high degree of accuracy and negligible edge damage.

The term “pick-and-place machine” will be understood by a person skilled in the art and may encompass a robotic machine used to place surface-mount devices (SMDs) onto a printed circuit board (PCB). Commercial examples of suitable pick-and-place machines include Datacon EVO 2200, Infotech Die bonder, and ASM ForceVector. The pick-and-place machine comprises a placement head (also known as a bonding head or pick-up head). The placement head is used to pick-up and position the preform, to attach the sinterable film to the substrate, and to separate the support film from the sinterable film. The placement head typically comprises vacuum functionality. Such functionality may be used to pick-up the preform. The placement head may also comprise gas purging functionality. The placement head may also comprise a heating functionality. Such heating functionality may be employed to heat the preform, and may facilitate tacking of the film and separation of the support film from the sinterable film.

The method comprises picking up the preform via the second surface using the placement head of the pick-and-place machine. In other words, during the picking up, the placement head contacts only the second surface of the preform and does not contact the first surface of the preform or the sinterable film. As a result, damage to the sinterable film may be avoided during the picking up and placing. This may avoid the formation of a compromised joint when the sintering film is sintered during an SMT process, for example a joint between a die and substrate that exhibits unfavourable thermal, electrical and/or mechanical properties.

The method comprises attaching the sinterable film to the substrate. The attaching is typically carried out by the application of heat and/or pressure. Attachment typically occurs due to a slight infusion of the metal particles into the substrate.

The method comprises separating the support film from the sinterable film. The support film may then be discarded. Alternatively, the support film may be used to manufacture a further preform. Separation may occur due to, for example, evaporation of organic compounds (e.g. binder) contained in the sinterable film, which pushes the support film away from the sinterable film.

Preferably, the placement head comprises a vacuum nozzle, and picking up the preform via the support film comprises applying a vacuum to the second surface using the vacuum nozzle. A vacuum may be particularly suitable for picking up the sinterable film, and when applied to second surface, i.e. the uncoated surface, may avoid damage to the sinterable film. By picking up the prefrom via the second surface, metal particles from the sintering film are not sucked into the pick and place machine and ultimately into the vacuum pump.

Separating the support film from the sinterable film is preferably carried out by moving the placement head of the pick-and-place machine away from the support film while maintaining the vacuum.

Preferably, the method further comprises discarding the support film from the pick-and-place machine by removing the vacuum.

In a preferred embodiment: the vacuum nozzle is capable of supplying a purging gas, and the vacuum nozzle supplies purging gas at the same time as removing the vacuum.

Placing the preform in contact with the substrate preferably comprises placing the preform in contact with a cavity or recess of the substrate. In contrast to conventional methods, the method of the present invention is capable of placing the preform in such hard-to-reach places. Accordingly, in contrast to conventional methods, the method of the present invention may be used to manufacture more complicated devices and/or may be used to manufacture such devices more easily.

Picking up the preform via the support film using the placement head of the pick-and-place machine preferably comprises picking up the preform from a holding carrier, more preferably a holding carrier in the form of a waffle pack, a carrier tape or a spooled tape-and-reel station.

In a preferred embodiment, the method further comprises:
providing a further preform comprising a further support film, the further support film having a first surface and a second surface opposite the first surface, the further support film being laminated with a further sinterable film of metal particles on the first surface but not on the second surface;
picking up the preform via the second surface of the further support film using the placement head of the pick-and-place machine,
placing the preform in contact with the sinterable film using the pick-and-place machine, wherein the contact is via the further sinterable film;
attaching the further sinterable film to the sinterable film; and
separating the further support film from the further sinterable film.

This may increase the thickness of a sintered joint formed using the sinterable film and the further sinterable film.

The support film preferably comprises polymer or the support film comprises a polymeric support film. Polymer may be particularly suitable for supporting the sinterable film and may be particularly suitable for being handled by the pick-and-place machine.

The substrate is preferably selected from a Direct Bonded Copper (DBC) substrate, an Active Metal Brazed (AMB) substrate a semiconductor surface in the form of a gate pad, a source pad, a drain pad, a collector pad, a silicon wafer substrate, a heat spreader, a metallic connector and a piezoelectric substrate. Such substrates may contain hard-to-reach places such as recesses. As discussed above, the method of the present invention may be capable of applying sinterable film to such places.

The preform preferably has a longest dimension of from 0.5 mm to 40 mm. When the preform is in the shape of a disc, the longest dimension is the diameter of the disc.

The preform is preferably the shape of a square, a rectangle, a circle, and any polygonal shape that conforms to the general dimensions of the target substrate.

The support film preferably has a thickness of from 40 to 80 μm. Smaller thicknesses may result in the support film breaking when being handled by the pick-and-place machine. Larger thicknesses may increase the cost of the support film.

The sinterable film preferably has a thickness of from 30 to 120 μm. A sintered joint formed from the sinterable film may exhibit unfavoruable mechanical and/or thermal properties if the thickness is smaller than 30 μm. Thicknesses larger than 120 82 m may unfavourably increase the size of the final device and may increase the cost of the sinterable film.

The metal particles are preferably selected from one or more of silver, silver alloys, gold, gold alloy, copper, copper alloy, palladium, palladium alloy, nickel, nickel alloy, aluminium and aluminium alloy, silver-coated copper, copper-coated silver, more preferably silver. Such metals are particularly suitable for use as sinterable particles in view of their favourable thermal, electrical and mechanical properties.

The metal particles preferably have a longest dimension of from 1 to 1000 nm, preferably from 2 to 500 nm, more preferably from 5 to 100 nm, even more preferably from 10 to 60 nm. When the particles are in the form of a sphere, the longest dimention is the diameter of the sphere. The longest dimension may be determined using a laser diffraction method. Smaller particles may be more difficult to handle. Larger particles may require a higher sintering temperature and/or pressure and/or time.

The sinterable film preferably comprises from 30 to 95 wt. % metal particles. Lower amounts may mean that a sintered joint formed from the sinterable film exhibits unfavourable mechanical, thermal and/or electrical properties. Higher amounts may result in oxidation and/or coalescence of the metal particles.

The metal particles are preferably capped with a capping agent, more preferably selected from one or more of a fatty acid, a fatty amine and starch. The presence of a capping agent may hinder the oxidation and/or coalescence of the metal particles.

The sinterable film preferably comprises from 0.1 to 20 wt. % capping agent, more preferably from 0.5 to 0.8 wt. % capping agent or from 0.8 to 1.5 wt. % capping agent. Lower amounts of capping agent may be insufficient to hinder oxidation and/or coalescence of the metal particles. Higher amounts may increase the amount of organics present in a sinterable joint formed from the sinterable film, thereby adversely affecting the mechanical, thermal or electrical properties of the joint.

Preferably, the metal particles comprise silver particles and the sinterable film is substantially devoid (more preferably entirely devoid) of particles of copper, aluminum, glass, carbon and graphite.

The sinterable film is preferably devoid of a silver foil layer.

The sinterable film preferably comprises a binder, more preferably a binder having a softening point of from 50 to 170° C., still more preferably from 70 to 120° C. Higher softening points may increase the amount of binder that remains in the sintered joint, thereby potentially adversely affecting the mechanical, thermal and/or electrical properties of the sintered joint. In addition, higher softening points may make it harder for the particles of the metal powder to sinter. Lower softening points may result in the sintering film losing its structural integrity during pick-up or placement.

The binder preferably comprises a resin and/or a rosin, more preferably a hydrogenated rosin. The presence of such species may remove surface oxides from the substrate and/or metal particles.

The sinterable film preferably comprises from 0.5 to 5 wt. % binder. Lower amounts may be insufficient to act as a binder. Higher amounts may increase the amount of organic material present in the sintered joint.

The sinterable film preferably comprises a solvent, more preferably selected from one or more of terpineol, butyl carbitol and isopropanol. The solvent may dissolve the binder. Such solvents may substantially evaporate during typical sintering temperatures, thereby reducing the amount of organic material present in the final sintered joint.

The sinterable film preferably contains sufficient solvent to dissolve the binder. The sinterable film preferably comprises from up to 70 wt. % solvent, more preferably from 1 to 60 wt. % solvent, even more preferably from 10 to 30 wt. % solvent. Lower amounts of solvent may not adequately dissolve the binder. Higher amounts may increase the amount of organic material present in the final sintered joint.

The attaching is carried out at a temperature of from 130 to 170° C. and/or a pressure of from 2 to 5 MPa and/or for a time of from 100 to 2000 ms, preferably from 100 to 800 ms. Such conditions may be particularly effective to attach the sinterable film to the substrate. For example, the conditions may encourage the metal particles to infuse into the substrate and/or may result in evaporation of solvent. Higher temperatures and/or pressures and/or longer times may result in sintering of the metal particles. Lower temperatures and/or pressures and/or shorter times may result in inadequate attachment.

In a further aspect, the present invention provides a method of applying a sinterable film to a substrate during a surface mount technology (SMT) process, the method comprising:
providing a substrate;
providing a preform comprising a support film, the support film having a first surface and a second surface opposite the first surface, the support film being laminated with a sinterable film of metal particles on the first surface but not on the second surface;
placing the preform in contact with the substrate, wherein the contact is via the sinterable film;
attaching the sinterable film to the substrate, and
separating the support film from the sinterable film, wherein:
the placing is carried out using a pick-and-place machine, and
during the placing and the attaching, the pick-and-place machine contacts the second surface of the support film but does not contact the sinterable film.

The advantages and preferable features of the first aspect apply equally to this aspect.

In a further aspect, the present invention provides a method of forming a stack of sinterable films on a substrate during a surface mount technology (SMT) process, the method comprising:
applying a first sinterable film to a substrate using the method described herein; and
stacking sequentially one or more further sinterable films on the first sinterable film, each of the one or more further sinterable films being stacked using a method comprising:
   providing a further preform comprising a further support film, the further support film having a first surface and a second surface opposite the first surface, the further support film being laminated with a further sinterable film of metal particles on the first surface but not on the second surface;
   picking up the further preform via the second surface using the placement head of the pick-and-place machine;
   for the first of the one or more further sinterable films:
      placing the respective further preform in contact with the first sinterable film using the pick-and-place machine, wherein the contact is via the further sinterable film,
      attaching the further sinterable film to the first sinterable film, and
      separating the support film from the further sinterable film; and
   for the subsequent further sinterable films:
      placing the respective further preform in contact with the immediately preceding further sinterable film using the pick-and-place machine, wherein the contact is via the further sinterable film of the respective preform of the second or subsequent further sinterable film,
      attaching the further sinterable film to the immediately preceding further sinterable film; and
      separating the support film from the further sinterable film.

The advantages and preferable features of the first aspect apply equally to this aspect.

The thickness of the stack sinterable films can be controlled by controlling the number of sinterable films that are stacked. Controlling the thickness of the stack may allow one to control the thickness of a sintered joint formed from the stack. Thicker sintered joints may be beneficial, for example, when a substrate and die joined by the joint exhibit different coefficients of thermal expansion (CTEs).

In a preferred embodiment, the first sinterable film is formed of the same material as the one or more further sinterable films. In this case, mechanical, thermal and/or electrical properties of the sintered joint may be substantially constant across its thickness.

In an alternative preferred embodiment, the first sinterable film is formed of material having different mechanical and/or thermal and/or electrical properties to those of at least one of the one or more further sinterable films. In this case, the mechanical, thermal and/or electrical properties of the sintered joint may vary across its thickness. For example, when the joint is used to join a substate and die having different coefficients of thermal expansion (CTEs), the CTEs of the metals of the metal particles in the sinterable films can be controlled so that the CTE of the sintered joint varies across its thickness, i.e. to have a CTE on a substrate side portion of the joint closer to that of the substrate and a CTE on a die side of the joint closer to that of the die. Examples of suitable metals include iron-nickel alloys, copper-tungsten alloys and copper-molybdenum alloys. In another example, it may be desirable to introduce a sacrificial failure area in the joint so as to provide failure predictably and aid in module life-time prediction. Such a sacrificial zone may be introduced by ensuring that at least one of the sinterable films contains metal particles in which the metal has a lower tensile strength and/or yield strength than the metal of the metal particles in the other sinterable films.

In a preferred embodiment, two further sinterable films are stacked on the first sinterable film to form a stack having an inner sinterable film and two outer sinterable films, and wherein the inner sinterable film is formed of material (i.e. metal particles) having different mechanical and/or thermal properties to those of the material forming the two outer sinterable films. Preferably, the metal of the metal particles of the inner sinterable film have a lower tensile strength and/or yield strength to the metal of the metal particles of the outer sinterable films. On sintering the stack, the inner sinterable film may result in a sacrificial failure area.

Preferably, the method further comprises applying additive particles between the first sinterable film and a further sinterable film and/or between further sinterable films.

The additive particles preferably comprise particles having a higher thermal conductivity than the material of the first sinterable film and one or more further sinterable films. This may increase the thermal conductivity of the sintered joint. This may be beneficial when there is a need to remove heat from the die to the substrate.

The particles having a higher thermal conductivity than the material of the first sinterable film and one or more further sinterable films preferably comprises diamond. The particles, such as diamond, may be dispersed in a film of sinterable particles.

The additive particles comprise particles having a different Young's modulus than the material of the first sinterable film and one or more further sinterable films. This may reduce the overall stress on the sintered joint, thereby improving the reliability of the joint.

In a further aspect, the present invention provides a method of attaching a die to a substrate, the method comprising:
applying a sinterable film to a substrate using the method described herein or forming a stack of sinterable films on a substrate using the method described herein;
contacting a die with the sinterable film or stack of sinterable films; and
sintering the sinterable film or stack of sinterable films to attach the die to the substrate.

The advantages and preferable features of this aspect apply equally to this aspect.

In a preferred embodiment, the width of the sinterable film is smaller than the width of the die and the width of the substrate. This may result in an undercut. This may be beneficial when, for example, the die comprises edge passivation

Preferably, the die comprises edge passivation and the die is contacted with the sinterable film so that the sinterable film does not contact the edge passivation.

In a further aspect, the present invention provides a method of attaching a clip, bond pad or top-side bridging structure to a die, the method comprising:
providing a die attached to a substrate;
applying a sinterable film to the die,
contacting the sinterable film with a clip, bond pad or top-side bridging structure; and
sintering the sinterable film to attach the clip, bond pad or top-side bridging structure to the die, wherein:
applying the sinterable film to the die is carried out by a method comprising:
   providing a preform comprising a support film, the support film having a first surface and a second surface opposite the first surface, the support film being laminated with a sinterable film of metal particles on the first surface but not on the second surface,
   providing a pick-and-place machine comprising a placement head,
   picking up the preform via the second surface using the placement head of the pick-and-place machine,
   placing the preform in contact with the die using the pick-and-place machine, wherein the contact is via the second surface,
   attaching the sinterable film to the die, and
   separating the support film from the sinterable film.

The advantages and preferable features of the first aspect apply equally to this aspect.

As discussed above, in contrast to conventional methods, the method of the present invention is capable of applying a sinterable film to a die that is attached to a substrate. This may facilitate the attaching of a clip, bond pad or top-side bridging structure to the die.

In this aspect, the sinterable film preferably comprises a stack of sinterable films.

In a further aspect, the present invention provides a method of attaching a clip, bond pad or top-side bridging structure to a die, the method comprising:
attaching a die to a substrate using the method described herein;
applying a sinterable film to the die,
contacting the sinterable film with a clip, bond pad or top-side bridging structure; and
sintering the sinterable film to attach the clip, bond pad or top-side bridging structure to the die,
   wherein:
applying the sinterable film to the die is carried out by a method comprising:
   providing a preform comprising a support film, the support film having a first surface and a second surface opposite the first surface, the support film being laminated with a sinterable film of metal particles on the first surface but not on the second surface,
   providing a pick-and-place machine comprising a placement head,
   picking up the preform via the second surface using the placement head of the pick-and-place machine,
   placing the preform in contact with the die using the pick-and-place machine, wherein the contact is via the sinterable film,
   attaching the sinterable film to the die, and
   separating the support film from the sinterable film.

The advantages and preferable features of the first aspect apply equally to this aspect.

As discussed above, in contrast to conventional methods, the method of the present invention is capable of applying a sinterable film to a die that is attached to a substrate. This may facilitate the attaching of a clip, bond pad or top-side bridging structure to the die.

In this aspect, the sinterable film preferably comprises a stack of sinterable films.

In a further aspect, the present invention provides a method of manufacturing an electronic device, the method comprising:
attaching a die to a substrate using the method described herein;
attaching a clip, bond pad or top-side bridging structure to the die using the method described herein.

The advantages and preferable features of the first aspect apply equally to this aspect.

The electronic device is preferably a power module.

The invention will now be further described with reference to the following numbered clauses:
1. A method of applying a sinterable film to a substrate, the method comprising: providing a substrate;
   providing a preform comprising a support film, the support film having a first surface and a second surface opposite the first surface, the support film being laminated with a sinterable film of metal particles on the first surface but not on the second surface;
   placing the preform in contact with the substrate, wherein the contact is via the sinterable film;
   attaching the sinterable film to the substrate, and
   separating the support film from the sinterable film.
2. The method of clause 1, wherein the support film comprises polymer or the support film comprises a polymeric support film.
3. The method of clause 1 or clause 2, wherein the substrate is selected from a Direct Bonded Copper (DBC) substrate, an Active Metal Brazed (AMB) substrate, a semiconductor surface in the form of a Gate pad, or a Source pad, or a Drain pad or a Collector pad, a silicon wafer substrate, a silicon wafer substrate, a heat spreader, a metallic connector and a piezoelectric substrate.
4. The method of any preceding clause, wherein the preform has general dimensions ranging from 0.5 mm across up to 40 mm across in the shape of squares, rectangles, circles, and shapes that conform to the general dimensions of the attached substrate.
5. The method of any preceding clause, wherein the support film has a thickness of from 40 to 80 μm.
6. The method of any preceding clause, wherein the sinterable film has a thickness of from 30 to 120 μm.
7. The method of any preceding clauses wherein the sinterable film comprises metal particles, preferably selected from one or more of silver, silver alloys, gold, gold alloy, copper, copper alloy, palladium, palladium alloy, nickel, nickel alloy, aluminium and aluminium alloy.
8. The method of any preceding clause, wherein the metal particles have a longest dimension of from 1 to 1000 nm, preferably from 2 to 500 nm, more preferably from 5 to 100 nm, even more preferably from 10 to 60 nm.
9. The method of any preceding clause, wherein the sinterable film comprises from 30 to 95 wt. % metal particles.
10. The method of any preceding clause, wherein the metal particles are capped with a capping agent, preferably selected from one or more of a fatty acid, a fatty amine and starch.
11. The method of clause 10, wherein the sinterable film comprises from 0.1 to 20 wt. % capping agent, preferably from 0.5 to 0.8 wt. % capping agent or from 0.8 to 1.5 wt. % capping agent.
14. The method of any preceding clause, wherein the sinterable film comprises a binder, preferably having a softening point of from 50 tom 170° C., preferably from 70 to 120° C.
15. The method of clause 14, wherein the binder comprises a resin and/or a rosin, preferably a hydrogenated rosin.
16. The method of clause 14 or clause 15, wherein the sinterable film comprises from 0.5 to 5 wt. % binder.
17. The method of any preceding clause, wherein the sinterable film comprises a solvent, preferably selected from one or more of terpineol, butyl carbitol and isopropanol.
18. The method of clause 17, wherein the sinterable film comprises from up to 70 wt. % solvent, preferably from 1 to 60 wt% solvent, more preferably from 10 to 30 wt. % solvent.
19. The method of any preceding clause, wherein the attaching is carried out at a temperature of from 130 to 170° C. and/or a pressure of from 2 to 5 MPa and/or for a time of from 100 to 2000 ms, preferably from 100 to 800 ms.
20. The method of any preceding clause, wherein:
   the placing is carried out using a pick-and-place machine; and
   during the placing and the attaching, the pick-and-place machine contacts the second surface of the support film but does not contact the sinterable film.
21. The method of any preceding clause, wherein:
   the placing is carried out using an automated pick-and-place machine; and
   during the picking up, placing and the attaching process, the pick-and-place machine contacts the second surface of the support film but does not contact the sinterable film.
22. The method of clause 20 or 21, wherein the pick-and-place machine comprises a bonding head tool with vacuum and air purging functionality.
23. The method of any of clauses 20 to 22, wherein during the placing, the attaching and/or the separating, the pick-and-place machine, preferably the bonding head tool of the pick-and-place machine, is maintained in contact with the second surface using a vacuum.
24. The method of clause 23, wherein separating the support film from the sinterable film is carried out by moving the placement head of the pick-and-place machine away from the sintering film while maintaining the vacuum.
25. The method of clause 24, wherein the support film is discarded from the pick-and-place machine by removing/reversing the vacuum.
26. The method of any preceding clause carried out during a surface mount technology (SMT) process.
27. The method of any preceding clause, wherein placing the preform in contact with the substrate comprises placing the preform in contact with a cavity/recess of the substrate.
28. The method of any preceding clause, further comprising:
   providing a further preform comprising a support film, the support film having a first surface and a second surface opposite the first surface, the support film being laminated with a further sinterable film of metal particles on the first surface but not on the second surface;
   placing the further preform in contact with the sinterable film, wherein the contact is via the further sinterable film;
   attaching the further sinterable film to the sinterable film, and
   separating the support film from the further sinterable film.
29. The method of any preceding clause, further comprising contacting the sinterable silver film or further sinterable silver film with a component, preferably selected from a die, a wafer, a bond pad, a secondary ceramic substrate, a copper wire and a copper ribbon.
30. The method of clause 29, further comprising sintering the sinterable film, and optionally the further sinterable film, to attach the component to the substrate.

The present invention will now be described further with reference to the following drawings in which:

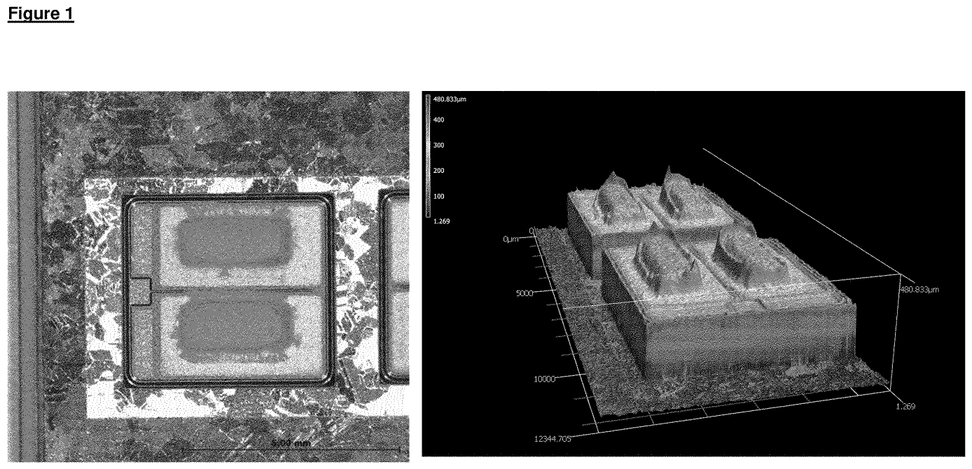

FIG. 1 shows images of printed paste on top of a die in accordance with conventional methods.

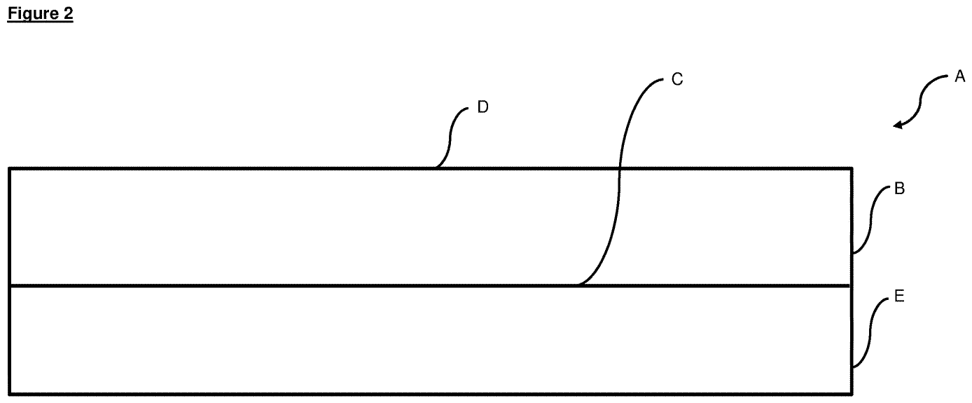

FIG. 2 shows a schematic of a preform in accordance with the present invention.

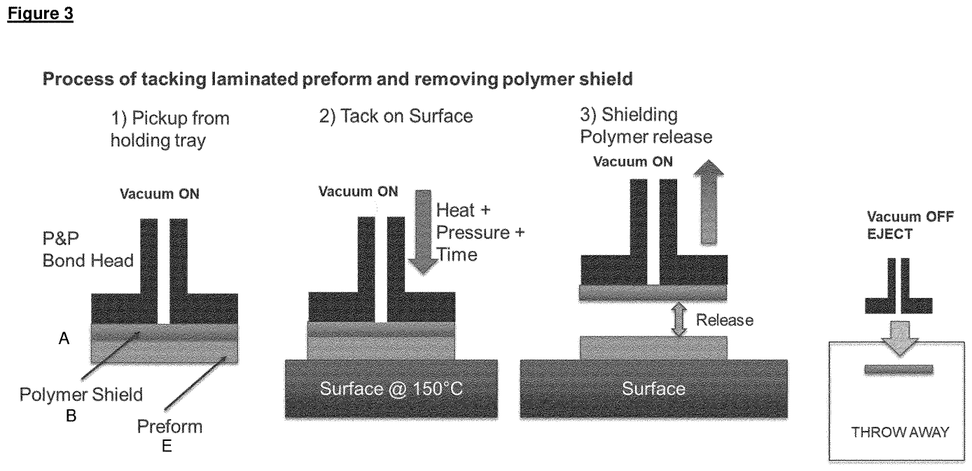

FIG. 3 shows a schematic of a method according to the invention.

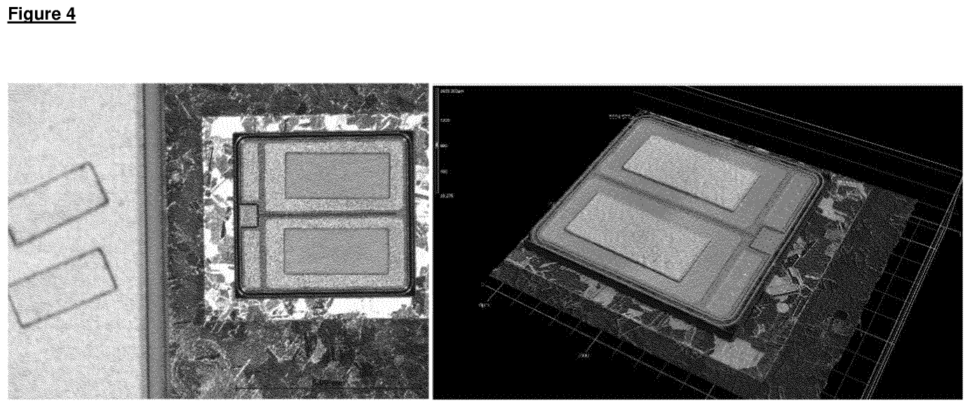

FIG. 4 shows images of a sinterable film applied to a substrate using the method shown in FIG. 3.

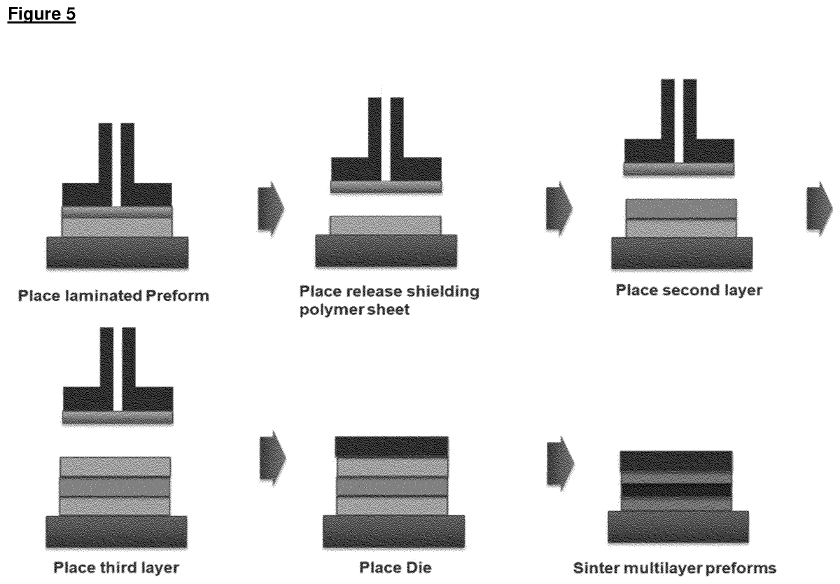

FIG. 5 shows a schematic of a method according to the invention.

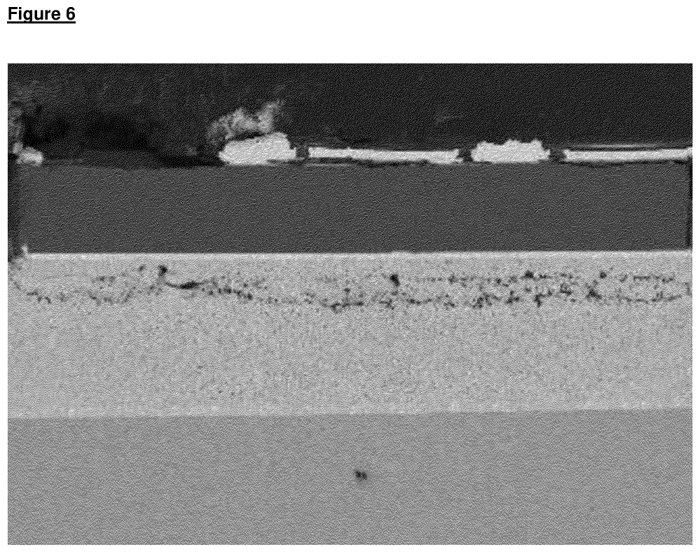

FIG. 6 shows an image of a sinterable film applied to a substrate using the method shown in FIG. 5.

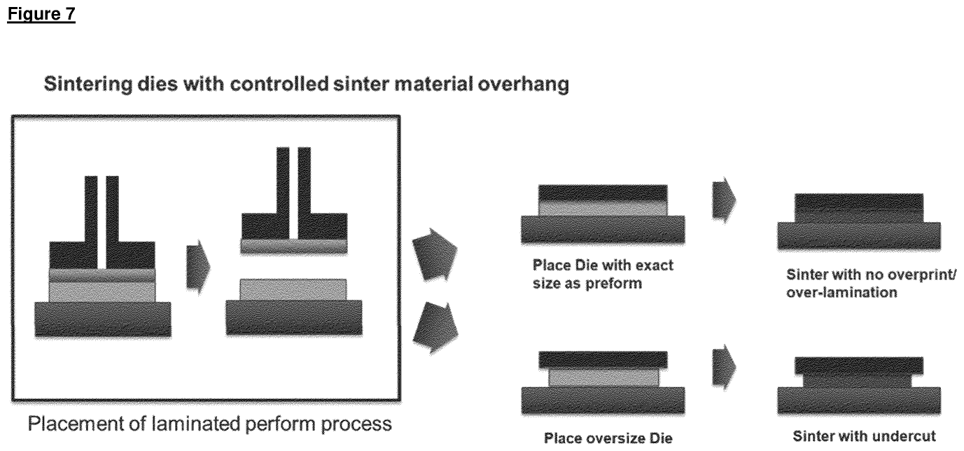

FIG. 7 shows a schematic of a method according to the invention.

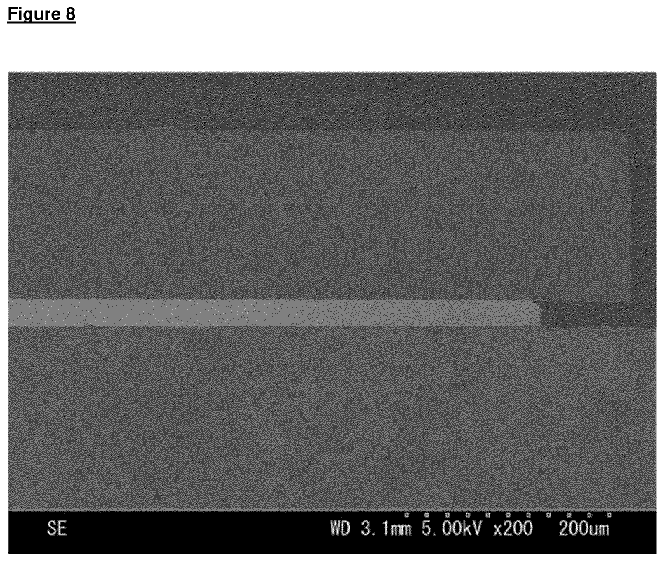

FIG. 8 shows a SEM image of a die sintered on top of a copper substrate using the method of FIG. 7.

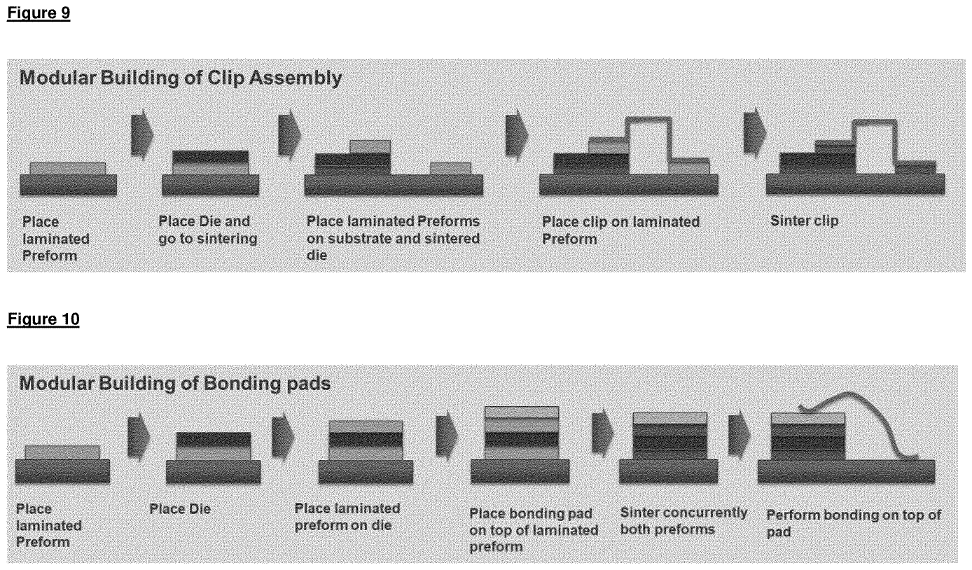

FIG. 9 shows a schematic of a method according to the invention.

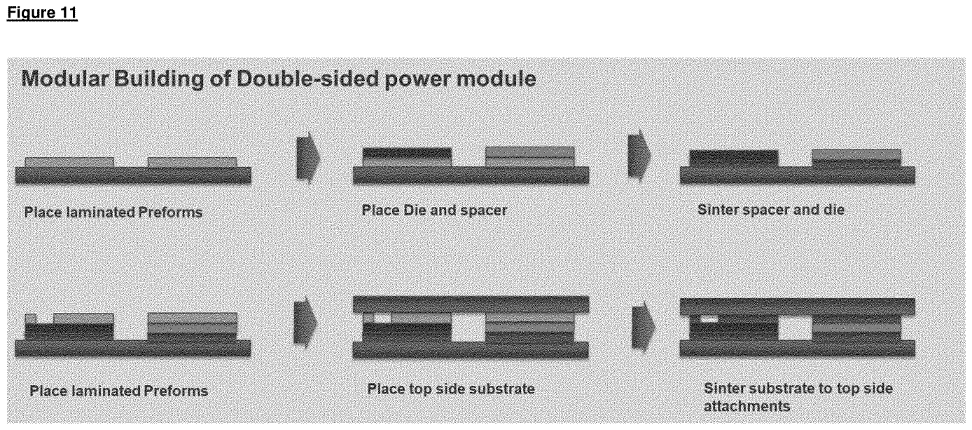

FIG. 10 shows a schematic of a method according to the invention.

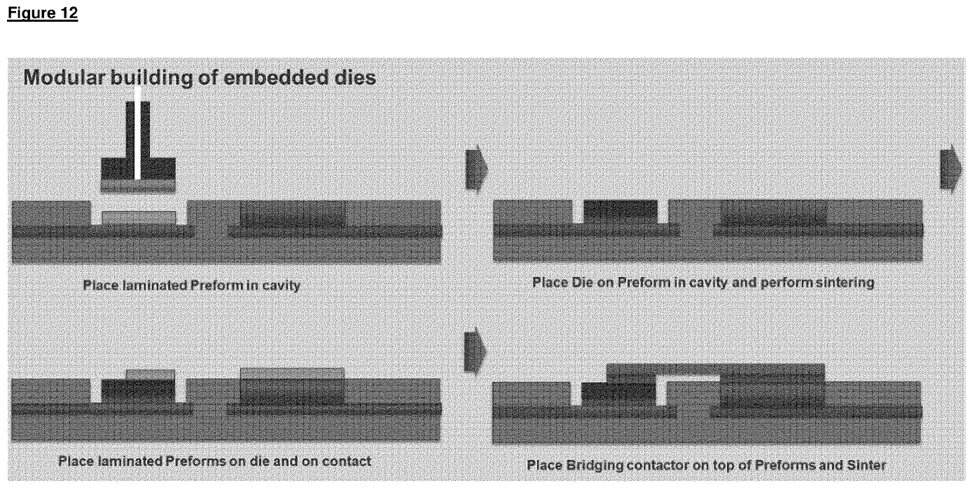

FIG. 11 shows a schematic of a method according to the invention.

FIG. 12 shows a schematic of a method according to the invention.

Referring to FIG. 1, there is shown paste applied to a die using a conventional printing method. As can be seen, there are problems with paste leakage and stencil separation.

Referring to FIG. 2, there is shown a schematic of a preform (shown generally at A) comprising a support film B having a first surface C and a second surface D. The first surface is laminated with a sinterable film of metal particles E.

Referring to FIG. 3, there is shown a schematic of a method according to the present invention. In step 1, the pick-and-place bond head picks up the preform A shown in FIG. 2 by the support film B using a vacuum. In step 2, the preform A is contacted with a substrate/die at a temperature of 150° C. to attach the sinterable film E. In step 3, while retaining the vacuum, the bond head is moved away from the substrate/die to separate the support film from the sinterable film. Finally, as shown on the right-hand side of FIG. 3, the support film is discarded by turning off the vacuum.

Referring to FIG. 4, there is shown images of a sinterable film applied to a top side of a die using the method shown in FIG. 3. The left-hand image shows a macro image with the polymer support films removed and set on one side. The right-hand laser scanning image shows good homogeneity and planarity.

Referring to FIG. 5, there is shown a method of forming a stack of sinterable films on a substrate during a surface mount technology (SMT) process. A preform is applied to a substrate using a pick-and-place machine. The support film is then removed from the sinterable film. A second sinterable film is then applied to the first sinterable film, followed by a third sinterable film being applied to the second sinterable film. A die is then applied to the stack of sinterable films. The second sinterable film has different material properties to the first and third sinterable films. The sinterable films are then sintered to form a sintered joint between the die and the substrate. In FIG. 5, the order of steps is: place laminated preform, place release shielding polymer sheet, please second layer, place third layer, place die, sinter multilayer preform.

Referring to FIG. 6 there is shown a SEM image of a stack of five sinterable films formed during the method shown in FIG. 5.

Referring to FIG. 7, there is shown a schematic of a method according to the present invention. The width of the sinterable film may be the same as (top) or smaller than (bottom) the with of the die. When the width of the sinterable film is smaller than the width of the die, an undercut is formed. In FIG. 6, the first step is placement of the laminated preform process. In the top scheme, the first step is to place die with exact size as preform and the second step is to sinter with no over-print/over-lamination. In the bottom scheme, the first step is to place the oversize die and the second step is to sinter with undercut. FIG. 8 shows a SEM image of a die sintered on top of a copper substrate using the method of the present invention to achieve an undercut of approximately 65 μm.

Referring to FIG. 9, there is shown a schematic of a method of attaching a clip to a die according to the present invention. A sinterable film is attached to a substrate and then a die is placed on the sinterable film. The order of step is: place laminated preform, place die and go to sintering, place laminated preforms on substrate and sintered die, place clip on laminated preform, sinter clip. The attachment of the clip may enable high current and low inductance circuits.

Referring to FIG. 10 there is shown a schematic of a method of attaching a bond pad to a die according to the present invention. The order of step is: place laminated preform, place die, place laminated preform on die, place bonding pad on top of laminated preform, sinter concurrently both preforms, preform bonding on top of pad. Bond pads consist of a buffering layer between the sensitive topside metals of the die and harsh interconnect methods such as copper wire or copper ribbon bonding which require high forces and ultrasonic energies

Referring to FIG. 11 there is shown a schematic of a method of attaching a top side bridging structure to a die according to the present invention. The order of steps is: place laminated preforms, place die and spacer, sinter spacer and die, place laminated preforms, place top side substrate, sinter substrate to top side of attachments. The method may result in a double side cooled module, where the drain and source connections of the die are sintered to planar substrates to improve cooling potential and increase the volumetric density of a power module.

Referring to FIG. 12, there is shown a schematic of a method of according to the present invention in which the sinterable film is applied to a cavity of a substrate. The order of steps is: place laminated preform in cavity, place die on preform in cavity and perform sintering, place laminated preforms on die and on contact, place bridging contactor on top of preforms and sinter.

The foregoing detailed description has been provided by way of explanation and illustration and is not intended to limit the scope of the appended claims. Many variations in the presently preferred embodiments illustrated herein will be apparent to one of ordinary skill in the art, and remain within the scope of the appended claims and their equivalents.

1. A method of applying a sinterable film to a substrate during a surface mount technology (SMT) process, the method comprising:
providing a substrate;
providing a preform comprising a support film, the support film having a first surface and a second surface opposite the first surface, the support film being laminated with a sinterable film of metal particles on the first surface but not on the second surface;
providing a pick-and-place machine comprising a placement head;
picking up the preform via the second surface using the placement head of the pick-and-place machine
placing the preform in contact with the substrate using the pick-and-place machine, wherein the contact is via the sinterable film;
attaching the sinterable film to the substrate; and
separating the support film from the sinterable film.

2. The method of claim 1, wherein:
the placement head comprises a vacuum nozzle, and
picking up the preform via the support film comprises applying a vacuum to the second surface using the vacuum nozzle.

3. The method of claim 2, wherein separating the support film from the sinterable film is carried out by moving the placement head of the pick-and-place machine away from the support film while maintaining the vacuum.

4. The method of claim 3, further comprising discarding the support film from the pick-and-place machine by removing the vacuum.

5. The method of claim 4, wherein:
the vacuum nozzle is capable of supplying a purging gas, and
the vacuum nozzle supplies purging gas at the same time as removing the vacuum.

6. The method of claim 1, wherein placing the preform in contact with the substrate comprises placing the preform in contact with a cavity or recess of the substrate.

7. The method of claim 1, wherein picking up the preform via the support film using the placement head of the pick-and-place machine comprises picking up the preform from a holding carrier, preferably a holding carrier in the form of a waffle pack, a carrier tape or a spooled tape-and-reel station.

8. The method of claim 1, further comprising:
providing a further preform comprising a further support film, the further support film having a first surface and a second surface opposite the first surface, the further support film being laminated with a further sinterable film of metal particles on the first surface but not on the second surface;
picking up the preform via the second surface of the further support film using the placement head of the pick-and-place machine,
placing the preform in contact with the sinterable film using the pick-and-place machine, wherein the contact is via the further sinterable film;
attaching the further sinterable film to the sinterable film; and
separating the further support film from the further sinterable film.

9-46. (canceled)

47. The method of claim 1, wherein:
the support film comprises polymer or the support film comprises a polymeric support film; and/or
the substrate is selected from a Direct Bonded Copper (DBC) substrate, an Active Metal Brazed (AMB) substrate, a semiconductor surface in the form of a gate pad, a source pad, a drain pad. a collector pad, a silicon wafer substrate, a heat spreader, a metallic connector and a piezoelectric substrate; and/or
the preform has a longest dimension of from 0.5 mm to 40 mm; and/or
the preform is in the shape of a square, a rectangle, a circle, and any polygonal shape that conforms to the general dimensions of the substrate; and/or
the support film has a thickness of from 40 to 80 μm; and/or
the sinterable film has a thickness of from 30 to 120 μm; and/or
the metal particles comprise silver particles and the sinterable film is substantially devoid of particles of copper, aluminum, glass, carbon and graphite; and/or
the sinterable film is devoid of a silver foil layer; and/or
the sinterable film comprises non-metallic particles, preferably in an amount of from greater than 0 to 30 wt. %, more preferably in an amount of from 1 to 30 wt. %, more preferably wherein the non-metallic particles are selected from one or more of carbon, silicon carbide, aluminum nitride, boron nitride and silicon dioxide, in coated or uncoated forms; and/or
the attaching is carried out at a temperature of from 130 to 170° C. and/or a pressure of from 2 to 5 MPa and/or for a time of from 100 to 2000 ms, preferably from 100 to 800 ms; and/or
placing the preform in contact with the substrate comprises placing the preform in contact with a cavity or recess of the substrate; and/or
picking up the preform via the support film using the placement head of the pick-and-place machine comprises picking up the preform from a holding carrier, preferably a holding carrier in the form of a waffle pack, a carrier tape or a spooled tape-and-reel station; and/or
the sinterable film comprises a solvent, preferably selected from one or more of terpineol, butyl carbitol and isopropanol, preferably wherein the sinterable film comprises from up to 70 wt. % solvent, preferably from 1 to 60 wt. % solvent, more preferably from 10 to 30 wt. % solvent.

48. The method of claim 1, wherein the metal particles are selected from one or more of silver, silver alloys, gold, gold alloy, copper, copper alloy, palladium, palladium alloy, nickel, nickel alloy, aluminium and aluminium alloy, silver-coated copper, copper-coated silver, more preferably silver;
preferably wherein the metal particles have a longest dimension of from 1 to 1000 nm, preferably from 2 to 500 nm, more preferably from 5 to 100 nm, even more preferably from 10 to 60 nm;
preferably wherein the sinterable film comprises from 30 to 95 wt. % metal particles;
preferably wherein the metal particles are capped with a capping agent, preferably selected from one or more of a fatty acid, a fatty amine and starch;
preferably wherein the sinterable film comprises from 0.1 to 20 wt. % capping agent, preferably from 0.5 to 0.8 wt. % capping agent or from 0.8 to 1.5 wt. % capping agent.

49. The method of claim 1, wherein the sinterable film comprises a binder, preferably having a softening point of from 50 to 170° C., more preferably from 70 to 120° C. ;
preferably wherein the binder comprises a resin and/or a rosin, preferably a hydrogenated rosin;
preferably wherein the sinterable film comprises from 0.5 to 5 wt. % binder.

50. A method of forming a stack of sinterable films on a substrate during a surface mount technology (SMT) process, the method comprising:
applying a first sinterable film to a substrate using the method of claim 1; and
stacking sequentially one or more further sinterable films on the first sinterable film, each of the one or more further sinterable films being stacked using a method comprising:
providing a further preform comprising a further support film, the further support film having a first surface and a second surface opposite the first surface, the further support film being laminated with a further sinterable film of metal particles on the first surface but not on the second surface;
picking up the further preform via the second surface using the placement head of the pick-and-place machine;
for the first of the one or more further sinterable films:
placing the respective further preform in contact with the first sinterable film using the pick-and-place machine, wherein the contact is via the further sinterable film,
attaching the further sinterable film to the first sinterable film, and
separating the support film from the further sinterable film; and
for the subsequent further sinterable films:
placing the respective further preform in contact with the immediately preceding further sinterable film using the pick-and-place machine, wherein the contact is via the further sinterable film of the respective preform of the second or subsequent further sinterable film;
attaching the further sinterable film to the immediately preceding further sinterable film; and
separating the support film from the further sinterable film.

51. The method of claim 50, wherein:
the first sinterable film is formed of the same material as the one or more further sinterable films; and/or
the first sinterable film is formed of material having different mechanical and/or thermal properties to those of at least one of the one or more further sinterable films, preferably wherein two further sinterable films are stacked on the first sinterable film to form a stack having an inner sinterable film and two outer sinterable films, and wherein the inner sinterable film is formed of material having different mechanical and/or thermal properties to those of the material forming the two outer sinterable films.

52. The method of claim 50, wherein the method further comprises applying additive particles between the first sinterable film and a further sinterable film and/or between further sinterable films, preferably wherein the additive particles comprise particles having a higher thermal conductivity than the material of the first sinterable film and one or more further sinterable films, more preferably wherein the additive particles having a higher thermal conductivity than the material of the first sinterable film and one or more further sinterable films comprises diamond, preferably wherein the additive particles comprise particles having a different Young's modulus than the material of the first sinterable film and one or more further sinterable films.

53. A method of attaching a die to a substrate, the method comprising:
applying a sinterable film to a substrate using a method of applying a sinterable film to a substrate during a surface mount technology (SMT) process, the method comprising:
providing a substrate;
providing a preform comprising a support film, the support film having a first surface and a second surface opposite the first surface, the support film being laminated with a sinterable film of metal particles on the first surface but not on the second surface;
providing a pick-and-place machine comprising a placement head;
picking up the preform via the second surface using the placement head of the pick-and-place machine;
placing the preform in contact with the substrate using the pick-and-place machine,
wherein the contact is via the sinterable film;
attaching the sinterable film to the substrate; and
separating the support film from the sinterable film,
or forming a stack of sinterable films on a substrate using the method of claim 50;
contacting a die with the sinterable film or stack of sinterable films; and
sintering the sinterable film or stack of sinterable films to attach the die to the substrate.

54. The method of claim 53, wherein the width of the sinterable film is smaller than the width of the die and the width of the substrate, preferably wherein the die comprises edge passivation and the die is contacted with the sinterable film so that the sinterable film does not contact the edge passivation.

55. A method of attaching a clip, bond pad or top-side bridging structure to a die, the method comprising:
providing a die attached to a substrate;
applying a sinterable film to the die,
contacting the sinterable film with a clip, bond pad or top-side bridging structure; and
sintering the sinterable film to attach the clip, bond pad or top-side bridging structure to the die,
wherein:
applying the sinterable film to the die is carried out by a method comprising:
providing a preform comprising a support film, the support film having a first surface and a second surface opposite the first surface, the support film being laminated with a sinterable film of metal particles on the first surface but not on the second surface,
providing a pick-and-place machine comprising a placement head,
picking up the preform via the second surface using the placement head of the pick-and-place machine,
placing the preform in contact with the die using the pick-and-place machine, wherein the contact is via the second surface,
attaching the sinterable film to the die, and
separating the support film from the sinterable film.

56. The method of claim 55, wherein the sinterable film comprises a stack of sinterable films.

57. : A method of attaching a clip, bond pad or top-side bridging structure to a die, the method comprising:
attaching a die to a substrate using the method of claim 53;
applying a sinterable film to the die,
contacting the sinterable film with a clip, bond pad or top-side bridging structure; and
sintering the sinterable film to attach the clip, bond pad or top-side bridging structure to the die,
wherein:
applying the sinterable film to the die is carried out by a method comprising:
providing a preform comprising a support film, the support film having a first surface and a second surface opposite the first surface, the support film being laminated with a sinterable film of metal particles on the first surface but not on the second surface,
providing a pick-and-place machine comprising a placement head,
picking up the preform via the second surface using the placement head of the pick-and-place machine,
placing the preform in contact with the die using the pick-and-place machine, wherein the contact is via the sinterable film,
attaching the sinterable film to the die, and
separating the support film from the sinterable film.

58. The method of claim 57, wherein the sinterable film comprises a stack of sinterable films.
